(19) United States
(12) Patent Application Publication
(10) Pub. No.: US 2022/0123199 A1
(43) Pub. Date: Apr. 21, 2022

(54) PIEZOELECTRIC MATERIALS AND STRUCTURES BASED ON CELLULOSE NANOCRYSTALS

(71) Applicant: FPInnovations, Pointe-Claire (CA)

(72) Inventors: Wadood Y. HAMAD, Vancouver (CA); Chuanwei MIAO, Richmond (CA)

(21) Appl. No.: 17/274,879

(22) PCT Filed: Sep. 6, 2019
(86) PCT No.: PCT/CA2019/051248

§ 371 Date: Mar. 10, 2021

Related U.S. Application Data
(60) Provisional application No. 62/728,905, filed on Sep. 10, 2018.

(51) Int. Cl. H01L 41/18; C08L 1/04; C08L 29/04; H01L 41/37

(52) U.S. Cl. CPC H01L 41/183; C08L 1/04; C08L 29/04; C08L 2203/20; C08L 2203/16; C08L 2203/14; H01L 41/37

(57) ABSTRACT

This invention describes a type of all-organic piezoelectric material based on cellulose nanocrystals (CNCs). This type of material is flexible and transparent, and its properties can be tuned by adjusting the composition and ionic strength. The fabrication of this type of piezoelectric material can be carried out entirely in an aqueous medium and does not require high temperature poling and stretching treatment. It renders possible a commercially viable route to producing inexpensive, sustainable, eco-friendly high piezo-electric-response organic materials for sensors, transducers, actuators, and energy harvest applications.

### TECHNICAL FIELD

It is provided piezoelectric material comprising cellulose nanocrystals (CNCs) and methods of producing same.

### BACKGROUND

Piezoelectricity describes a phenomenon whereby an electric field is generated inside a material subjected to a mechanical force or vice versa. Piezoelectric materials are broadly used as sensors, actuators, transducers, and energy harvesters. The most extensively studied piezoelectric materials are semiconductors and ceramics due to their high piezoelectric coefficients. However, their applications are seriously limited where high flexibility is required, e.g., wearable electronics. Therefore, a combination of inorganic piezoelectric ceramics with flexible organic polymer matrices has been explored (Dagdeviren et al., 2015, Nat. Mater., 14: 728-736).

Organic piezoelectric materials are also attracting more and more research interests in recent years. The most common organic piezoelectric materials are fluoride polymers, including polyvinylidene fluoride (PVDF) and poly(vinylidene fluoride-trifluoroethylene) (PVDF-TrFE), and flexible piezoelectric devices based on these polymers through various processing and fabrication methods have been studied (Persano et al., 2013, Nat. Commun., 4: 1633; Cauda et al., 2013, ACS Appl. Mater. Inter., 5: 6430-6437).

Recently, all-organic polymer piezoelectric materials were prepared by doping molecules possessing large dipole moments in a polymer matrix (Moody et al., 2016, J. Mater. Chem. C, 4: 4387-4392; Ko et al., 2017, Adv. Mater., 29: 1603813). Despite the significant difference between all these materials, a common fact is that all of them need poling, through which the randomly oriented dipoles are aligned under a strong electric field. Such a procedure needs to be carried out under specifically controlled conditions, such as elevated temperature and strong electric field, which increase the complexity and cost for large-scale production.

There is thus still a need to develop improved organic piezoelectric materials and method of making same.

### SUMMARY

It is provided a piezoelectric material comprising cellulose nanocrystals (CNCs) and a solvent.

In an embodiment, the cellulose nanocrystals can be from bleached wood pulp, cotton, grass, wheat straw, bacteria cellulose, or tunicate.

In another embodiment, the cellulose nanocrystals' surfaces are further modified by ion-exchange, covalently grafting polymers or small molecules, or adsorption of small and controlled amounts of polymers or small molecules.

In an embodiment, the cellulose nanocrystals comprise sulfate half-ester, carboxylates or phosphates groups.

In a further embodiment, the cellulose nanocrystals comprise —SO₃H groups or —SO₃Na groups.

In another embodiment, the cellulose nanocrystals have a high dipole moment.

In an additional embodiment, the cellulose nanocrystals have a high dipole moment of 4400±400 D along CNC's long axis.

In a further embodiment, the solvent is water.

In an additional embodiment, the solvent is dimethyl sulfoxide (DMSO), N-methylpyrrolidone (NMP), dimethyl acetamide (DMA), N,N-dimethylformamide (DMF), pyridine, tetrahydrofuran (THF), or a combination thereof.

In an embodiment, the piezoelectric material described herein comprises 0.01-10 wt. % of CNCs in the solvent.

In another embodiment, the piezoelectric material described herein comprises an additive.

In a further embodiment, the additive is a polymer, a salt, or a combination hereof.

In an additional embodiment, the additive is sodium chloride.

In another embodiment, the concentration of sodium chloride in the solvent is 0.01-50 mM.

In a further embodiment, the piezoelectric material described herein comprises 3 mM of NaCl, or 0.0175 wt. %.

In another embodiment, the CNC nanoparticles form chiral nematic structure in the piezoelectric material described herein.

In an embodiment, the polymer is a polyethylene glycol, polyethylene oxide, polyacrylamide, polyvinyl alcohol, polyamines, polyethyleneimines, quaternary ammonium polymers, carboxymethylated polymers, polyvinylpyrrolidone and copolymers, polyacrylic acid and copolymers.

In an embodiment, the piezoelectric material described herein comprises 10-90 wt. %. of polymer.

In an additional embodiment, the piezoelectric material described herein comprises a ratio of polymer to CNCs of 1:1 by weight and a concentration of NaCl of 3 mM.

In another embodiment, the piezoelectric material is a film, powder or foam.

It is provided a method of preparing a piezoelectric material comprising the steps of dispersing cellulose nanocrystals (CNCs) in a solvent; and removing of the solvent to produce the piezoelectric material.

It is also provided a method of preparing a piezoelectric material comprising the steps of dispersing cellulose nanocrystals (CNCs) in a solvent, and removing of the solvent.

In an embodiment, the solvent is removed in the presence of an electric field applied to the CNC dispersed in the solvent.

In an embodiment, the solvent is removed by evaporation.

In another embodiment, the solvent is removed by evaporation from 0 to 100° C.

In a further embodiment, the solvent is removed by freeze drying or spray drying.

In a particular embodiment, the cellulose nanocrystals are prepared from bleached wood pulp by sulfuric acid hydrolysis.

In another embodiment, the electric field is a direct current or an alternating current source.

In an embodiment, the electric field is from 1 to 1,000 V/m.

It is provided a method of preparing piezoelectric actuator or transducer by sandwiching the CNC-based piezoelectric materials between two electrodes, followed by laminating the sandwiched structure using polymer films.

In an embodiment, the electrodes are metal foils, conductive coatings, conductive adhesives, conductive polymers, or sputter coated materials.

In another embodiment, the lamination polymer film is polyester, polyvinyl acetate, polyolefin, polyurethane, polyacrylates, polystyrene, halogenated polymers, polysaccharides, rubbers, or a co-polymer hereof.

In a particular embodiment, the polymer film comprises two layers: polyethylene terephthalate (PET) as the outer layer and ethylene-vinyl acetate (EVA) copolymer as the inner layer.

### BRIEF DESCRIPTION OF THE DRAWINGS

Reference will now be made to the accompanying drawings.

FIG. 1 illustrates a schematic representation of the process to produce CNC-based piezoelectric materials in accordance to an embodiment.

FIG. 2 illustrates the set-up for preparing CNC-based piezoelectric materials with the application of an electric field during casting.

FIG. 3 illustrates the pattern of the series of forces applied onto samples for measuring the piezoelectric coefficient, d₃₃, of the tested material, wherein a 1 N preload compressive force was applied onto the tested sample and maintained throughout the whole process; and a 20 N of compressive force was applied onto the tested sample repeatedly for 20 times, each of the force lasted for 0.1 s and there was a 5 s interval between each of them.

FIG. 4 illustrates four typical piezoelectric response curves of CNC-based piezoelectric materials showing in (a) a film cast from H-form CNC suspension; (b) a film cast from H-form CNC suspension under electric field; (c) a film cast from H-form CNC suspension containing 3 mM NaCl; and (d) a film cast from a suspension containing H-form CNCs, polyethylene oxide (PEO), and 3 mM NaCl; wherein the Y axis denotes the charge generated by the compressive force applied onto the tested samples and the X axis is time, each of the peaks represents the force pattern described in FIG. 3, and the piezoelectric coefficient, d₃₃, is calculated as charge/force and the unit is pC/N.

FIG. 5 illustrates the piezoelectric coefficients of PEO-CNC nanocomposite films prepared from suspensions containing different quantities of NaCl before casting, wherein in all samples, the ratio of CNCs to PEO is 1:1 by weight, and for each of the d₃₃ value, it is the average of the 20 measurements described in FIG. 4, and the error bars stand for the standard deviations.

FIG. 6 illustrates typical tensile stress-strain results of PEO and PEO-CNC nanocomposite films showing the CNC-based piezoelectric films are strong and flexible.

FIG. 7 shows a picture of a piece of actual PEO-CNC nanocomposite film showing its excellent flexibility.

FIG. 8 illustrates the structure of a piezoelectric transducer or actuator device using CNC-based piezoelectric material.

FIG. 9 illustrates piezoelectric response curves of two types of laminated CNC-based piezoelectric materials. The piezoelectric films are cast from H-form CNC suspension containing 3 mM NaCl. The lamination materials are bilayer films with polyethylene terephthalate (PET) as the outer layer and ethylene-vinyl acetate (EVA) as the inner layer. The electrode materials are (a) copper foil and (b) silver coating, respectively. The definition of X and Y axes are the same as in FIG. 4. The piezoelectric coefficient, d₃₃, is calculated as charge/force and the unit is pC/N.

It will be noted that throughout the appended drawings, like features are identified by like reference numerals.

### DETAILED DESCRIPTION

In accordance with the present description, there is provided CNC-based piezoelectric materials and the methods to produce them.

It is thus provided a category of all-organic piezoelectric materials based on cellulose nanocrystals (CNCs) prepared using a one-step, scalable process with no need for poling or stretching as the case may be with other materials.

Cellulose is the major constituent of wood and plant cell walls and is the most abundant biopolymer on the planet. Cellulose is therefore an extremely important resource for the development of sustainable technologies. Cellulose nanocrystals (CNCs) are extracted as a colloidal suspension by (typically sulfuric) acid hydrolysis of lignocellulosic materials, such as bacteria, cotton, wood pulp, tunicate and the like. CNCs characteristically possess a negative entity on the surface including, but not limited to, sulfate half-ester groups (—SO₃H or —SO₃Na), carboxylates (—COON or —COONa) or phosphates (O—PO₃H₂ or O—PO₃Na₂). In a preferred embodiment, the CNCs possess sulfate half-ester groups (—SO₃H or —SO₃Na). H₂SO₄-catalyzed CNCs have a specifically high dipole moment, ca. 4400±400 D, along the CNC's long axis (Frka-Petesic et al., 2014, EPL, 107: 28006). CNCs possess a high degree of crystallinity in the bulk material, while various degrees of order, or in other words different levels of amorphicity, may exist on the surface. The colloidal suspensions of CNCs is characterized as liquid crystalline at a critical concentration, ca. 5-7 wt. %, and the chiral nematic organization of CNCs remain unperturbed in films formed upon evaporation. CNCs also have a degree of crystallinity between about 85% and about 97%, more preferably between about 90% and about 97% (that is, approaching the theoretical limit of crystallinity of the cellulose chains), which is the ratio of the crystalline contribution to the sum of crystalline and amorphous contributions as determined from original powder X-ray diffraction patterns. Moreover, the CNCs may have a degree of polymerization (DP) of 90≤DP≤110, and between about 3.7 and about 6.7 sulphate groups per 100 anhydroglucose units (AGU).

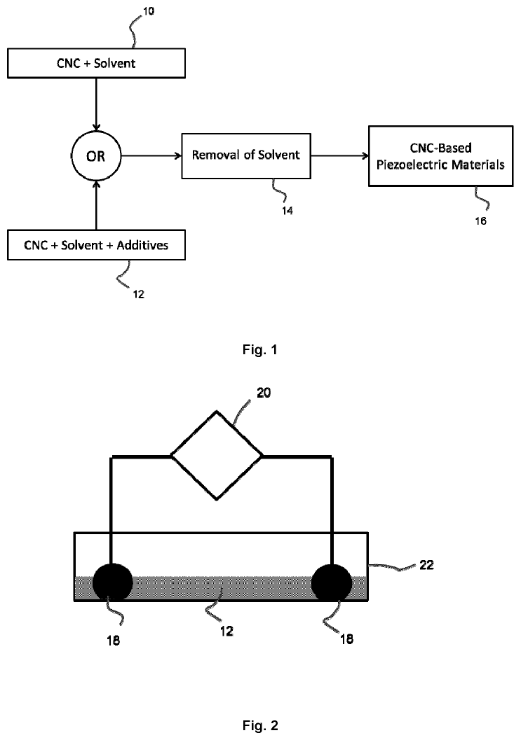

As described in FIG. 1, the material encompassed herein is prepared by dispersing CNCs 10 with/without additives in a solvent 12, typically water, followed by removal of the solvent 14. The additives include polymers and/or salts, and evaporation can be an effective method for solvent removal, with or without the application of an electric field. When a polymer or polymers are added in the solvent, CNC-reinforced nanocomposites are obtained. The quantity of salt in the suspension has a significant effect on the piezoelectric response of the final materials. By controlling the composition and the ionic strength, the properties of the obtained materials can be tuned. The final piezoelectric materials are typically highly transparent flexible thin films. Further, CNC-based piezoelectric materials do not require high temperature poling and/or stretching treatment, which are necessary for typical polymeric piezoelectric materials. The piezoelectric coefficient of CNC-based material is comparable to, or higher than, conventional polymeric piezoelectric materials.

As described herein, the CNCs used were produced from bleached wood pulp by sulfuric acid hydrolysis. However, CNCs produced from other biomass, such as, but not limited to, cotton, grass, wheat straw, bacterial cellulose and tunicate, can also be used. In a particular embodiment, the CNCs used are pristine. Alternatively, surface modified CNCs can also be used. The modifications include for example, but not limited to, ion-exchange, covalently grafting polymers or small molecules, or adsorption of small and controlled amounts of polymers or small molecules.

The preparation of CNC-based piezoelectric materials 16 normally starts from suspension of CNCs 10, and the solvent of the suspension is typically water. Other solvents/additives that can disperse CNCs can also be potentially used, e.g. dimethyl sulfoxide (DMSO), N-methylpyrrolidone (NMP), dimethyl acetamide (DMA), N,N-dimethylformamide (DMF), pyridine, tetrahydrofuran (THF), etc. The concentration of CNCs in the solvent may vary in a wide range, e.g. 0.01-10 wt. %. The solvent of CNC suspension can be removed 14 by evaporation in a container, whereby CNC films are obtained, which are the piezoelectric materials 16 (FIG. 1). The evaporation of solvent can be carried out at temperatures ranging from the melting point to the boiling point of the solvent, for example 0 to 100° C. in the case of water. When other drying methods are employed, say freeze drying or spray drying, different forms of CNC-based piezoelectric materials can be obtained.

In order to improve the piezoelectric response of CNC films, an electric field is applied using a power supply 20 in the CNC suspension 12 in a container 22 during the process of solvent evaporation 14. The electric field should be applied by two electrodes 18 placed in the CNC suspension 12 as seen in FIG. 2. The electric field can be either direct current or alternating current source. The strength of the electric field may vary from 1 to 1,000 V/m.

The CNCs hydrolyzed by sulfuric acid possess sulfuric ester groups on the surfaces. The counter ions associated with these sulfuric ester groups have significant effect on the piezoelectric properties of final materials. When these groups are associated with metal ions, the films formed from this type of CNCs show limited piezoelectric response. For example, for the CNCs associated with sodium ions (Na—CNC), the piezoelectric coefficient, d₃₃, of films prepared from this type of CNCs is only 0.3-0.4 pC/N. However, when these sulfuric ester groups are protonated with hydrogen via ion-exchange, i.e., the CNCs are in acidic form (H—CNC), films prepared from this type of CNCs show piezoelectric response of 5-6 pC/N.

The piezoelectric response of H—CNC films can be further improved by adding additives in the solvent before formation of the films. A typical additive is sodium chloride (NaCl). However, any ionic compounds that are composed of cations and anions can be used. The quantity of salt may vary in a wide range, e.g., 0.03 to 300 mM in the solvent. The piezoelectric response of CNC films is very sensitive to the quantity of salt in the system. In the case of NaCl, the optimum concentration of NaCl in the CNC aqueous suspension is 3 mM. And the optimum salt concentration may change for different types of salt, or different types of CNCs.

Polymers can also be used as additives in CNC-based piezoelectric materials. In this case, the polymer is a matrix, which forms a nanocomposite with CNCs. Any polymer that can dissolve in the solvent, in which CNCs are dispersed, can be used as the matrix, such as polyethylene glycol, polyacrylamide, polyvinyl alcohol, polyamines, polyethyleneimines, quaternary ammonium polymers, carboxymethylated polymers, polyvinylpyrrolidone and copolymers, polyacrylic acid and copolymers, etc. In the case of CNC aqueous suspension, there are two examples of such polymer. One is polyethylene oxide (PEO), with a molecular weight ranging from 100,000 to 6,000,000 Da; and the other is polyvinyl alcohol, with a molecular weight ranging from 10,000 to 3,000,000 Da and hydrolysis degree of 50-100%. The quantity of polymer in the final CNC-based nanocomposite may vary in the range of 10-90 wt. %. The addition of proper polymers can render CNC-based piezoelectric materials excellent flexibility, as well as good transparency. Salt can be added together with polymers in CNC suspensions to improve the piezoelectric response of the final material. However, addition of salt into polymer solutions alone (without CNCs) cannot achieve the same high piezoelectric response.

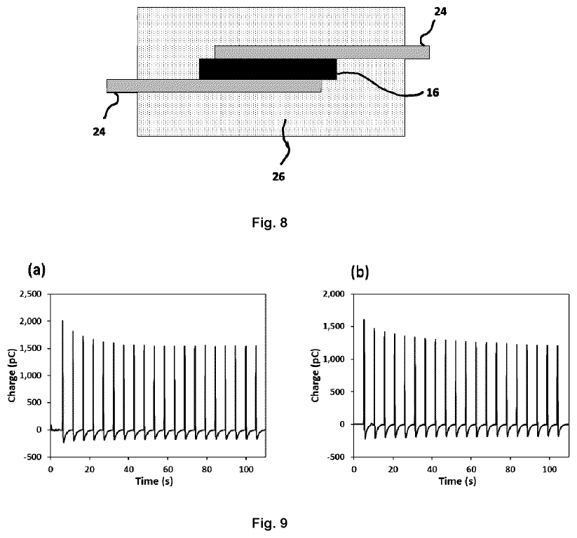

The CNC-based piezoelectric materials prepared through the method described above can be assembled into a piezoelectric actuator or transducer. In such a device, the piezoelectric material 16 is sandwiched between two electrodes 24. The sandwiched structure is then laminated with polymer films 26 (FIG. 8). The electrodes can be metal foils, conductive coatings, conductive adhesives, conductive polymers, or sputter coated materials. The lamination polymer is typically a bilayer film comprising of polyethylene terephthalate and ethylene-vinyl acetate copolymer. The lamination materials can also be polyester, polyvinyl acetate, polyolefin, polyurethane, polyacrylates, polystyrene, halogenated polymers, polysaccharides, rubbers, or a co-polymer hereof.

The present description will be more readily understood by referring to the following examples.

### Example I

### Preparation of CNC-Based Piezoelectric Materials

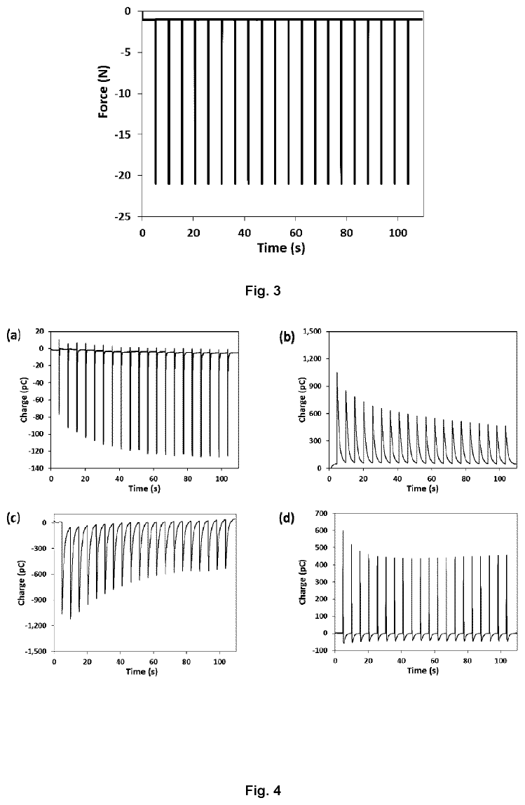

All samples described here were prepared by casting from aqueous suspensions in Petri dishes under room temperature. The obtained samples were films with thickness of ca. 30 μm. To test the piezoelectric response, the sample film was sandwiched between two flat copper electrodes. Controlled compressive forces were applied onto this assembly using a tensiometer. A 1 N preload force was applied and maintained throughout the entire testing process to ensure proper contact between the tested sample and electrodes. After 5 s, a 20 N compressive force was exerted on the sample and repeated for 20 times with a 5 s interval between them. Each of the force load lasted for 0.1 s. The pattern of the force load is depicted in FIG. 3. The charge generated by each loaded force was measured by a charge meter connected to the two electrodes. The piezoelectric coefficient was calculated as charge/force and the unit is pC/N.

An aqueous suspension of H-form CNCs (2 wt. %) was cast in a Petri dish and the piezoelectric response of the resulting film under load is given in FIG. 4a. This type of film has a moderate piezoelectric coefficient. The average d₃₃ of 20 measurements is 5.6 pC/N.

Further, the same CNC suspension was cast with the application of an electric field during casting. In this case, two graphite rods were placed into the Petri dish at a distance of 2 cm during casting. A DC of 6.5 V was applied onto the two graphite rods for 30 min and turned off for another 30 min. This cycle was repeated for 10 hours in total. The piezoelectric response of the films prepared in this method is shown in FIG. 4b. It has a higher piezoelectric response in the first load of force and attenuates gradually in subsequent repeated loading. The d₃₃ at the first load of force is 49.9 pC/N and the average value of the last 6 loads is 21.8 pC/N.

In addition, 3 mM NaCl was added into the same H—CNC suspension and cast in a Petri dish. The piezoelectric response result is given in FIG. 4c. This type of film also shows high initial d₃₃ and the values decreased gradually. The d₃₃ of initial and average of the last 6 loads was 53.4 and 27.7 pC/N, respectively. The concentration of NaCl in the CNC suspension has significant effect on the piezoelectric response of the resulting films. Table 1 gives the piezoelectric properties of H—CNC films prepared at different NaCl concentrations.

TABLE 1
Piezoelectric coefficients of H—CNC films prepared using
different NaCl concentrations in the suspensions

| NaCl concen- | | | |
|---|---|---|---|
| tration in | | | Average d₃₃ of |
| CNC | NaCl concen- | d₃₃ at the first | the last |
| suspension | tration | load of | 6 loads of force |
| (mM) | as wt. % | force (pC/N) | (pC/N) |
| 0.03 | 0.0002 | 15.8 | 2.9 |
| 0.3 | 0.0018 | 29.5 | 5.5 |
| 3 | 0.0175 | 53.3 | 27.7 |
| 5 | 0.0292 | 11.9 | 3.2 |

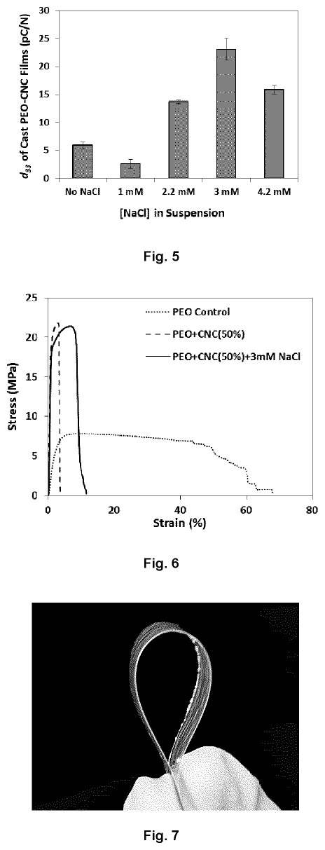

In another example, both NaCl and PEO were added into the H—CNC aqueous suspension before evaporation casting. The ratio of PEO to CNCs is 1:1 by weight and the concentration of NaCl is 3 mM. The piezoelectric response of the resulting film is shown in FIG. 4d. This type of film does not have significant extent change in d₃₃ during the 20 times of repeated loading. The concentration of NaCl in the CNC suspensions also affects the piezoelectric response of resulting films, which is shown in FIG. 5. The maximum value of d₃₃ is obtained at 3 mM of NaCl as well and the average d₃₃ is 23.1 pC/N. However, addition of NaCl to PEO alone cannot form a material with the same high piezoelectric response. For instance, PEO film cast from a solution containing 3 mM NaCl shows d₃₃ of 1.8 pC/N, a value similar to neat PEO, 1.2 pC/N. The addition of NaCl in PEO-CNC films not only improves their piezoelectric performance, but also imparts better flexibility. As shown in FIG. 6, PEO-CNC nanocomposite films have significantly higher strength and stiffness than the pure PEO film, but the strain at break is relatively lower. By adding 3 mM of NaCl in the suspension before casting, the strain at break is improved 3 times, yet the high strength and stiffness is maintained. The excellent flexibility of such a piezoelectric PEO-CNC nanocomposite film is shown in FIG. 7.

In a further example, H—CNC is cast with polyvinyl alcohol (PVA) from water in the same manner as the PEO examples. The H—CNC to PVA ratio is fixed at 1:1 by weight and the concentration of NaCl in the suspensions varied from 0 to 15 mM. The piezoelectric coefficients of the resulting films are shown in Table 2. Pure PVA films prepared through the same method (no H—CNC and NaCl) exhibits very low d₃₃, 0.2 pC/N. By mixing H—CNC with PVA alone, the d₃₃ is slightly increased to 0.9 pC/N only. However, addition of NaCl into CNC suspensions significantly improves the piezoelectric response of the resulting CNC/PVA films, and the maximum d₃₃ values are shown at NaCl concentration 5-7 mM.

TABLE 2
Piezoelectric coefficients of H—CNC/PVA films
prepared using different NaCl concentrations
in the suspensions.
The ratio of H—CNC to PVA is 1:1 by weight
for all films.

| NaCl concen- | | Average d₃₃ of |
|---|---|---|
| tration in CNC | NaCl concen- | 20 load |
| suspension | tration as | of force |
| (mM) | wt. % | (pC/N) |
| 0 | 0.0000% | 0.9 |
| 1 | 0.0058% | 3.9 |
| 3 | 0.0175% | 3.8 |
| 5 | 0.0292% | 10.1 |
| 7 | 0.0409% | 10.7 |
| 10 | 0.0584% | 4.2 |
| 15 | 0.0875% | 1.8 |

The piezoelectric films prepared through this method can be assembled into a piezoelectric actuator or transducer by sandwiching the films between two electrodes followed by lamination of the sandwiched structure using polymer films. In an example, H—CNC piezoelectric films are prepared from the suspension containing 3 mM NaCl using the method described above. The film is sandwiched between two copper foils and then laminated using a commercial thermal laminating film. The piezoelectric response curve of this piece of device under repeated compressive forces is shown in FIG. 9(a) and the average d₃₃ of the 20 measurements is 80.4 pC/N. In another example, silver coating is used as electrodes for laminating the same type of H—CNC piezoelectric film. In this case, the silver coating is applied onto the thermal laminating films and dried prior to lamination. The piezoelectric response curve of this piece of device is given in FIG. 9(b) and the average d₃₃ of the 20 measurements is 66.6 pC/N.

Depending on the composition, the piezoelectric coefficient of the material produced herein is comparable to, or even higher than, commercial polymeric piezoelectric materials, like polyvinylidene fluoride (PVDF).

While the disclosure has been described in connection with specific embodiments thereof, it will be understood that it is capable of further modifications and this application is intended to cover any variations, uses, or adaptations, including such departures from the present disclosure as come within known or customary practice within the art and as may be applied to the essential features hereinbefore set forth, and as follows in the scope of the appended claims.

What is claimed is:

1. A piezoelectric material comprising cellulose nanocrystals (CNCs) and a solvent.

2. The piezoelectric material of claim 1, wherein the cellulose nanocrystals are from bleached wood pulp, cotton, grass, wheat straw, bacteria cellulose, or tunicate.

3. The piezoelectric material of claim 1 or 2, wherein the cellulose nanocrystals comprise sulfate half-ester, carboxylates or phosphates groups.

4. The piezoelectric material of claim 3, wherein the cellulose nanocrystals comprise —SO₃H groups or —SO₃Na groups.

5. The piezoelectric material of any one of claims 1-4, wherein said cellulose nanocrystals have a high dipole moment.

6. The piezoelectric material of claim 5, wherein said cellulose nanocrystals have a high dipole moment of 4400±400 D along CNC's long axis.

7. The piezoelectric material of any one of claims 1-6, wherein the cellulose nanocrystals are further modified by ion-exchange, covalently grafting polymers or small molecules, or adsorption of small and controlled amounts of polymers or small molecules.

8. The piezoelectric material of any one of claims 1-7, wherein the solvent is water.

9. The piezoelectric material of any one of claims 1-7, wherein the solvent is dimethyl sulfoxide (DMSO), N-methylpyrrolidone (NMP), dimethyl acetamide (DMA), N,N-dimethylformamide (DMF), pyridine, tetrahydrofuran (THF), or a combination thereof.

10. The piezoelectric material of any one of claims 1-9, comprising 0.01-10 wt. % of CNCs in the solvent.

11. The piezoelectric material of any one of claims 1-10, further comprising an additive.

12. The piezoelectric material of claim 11, wherein the additive is a polymer, a salt, or a combination hereof.

13. The piezoelectric material of claim 12, wherein the additive is sodium chloride.

14. The piezoelectric material of claim 13, comprising 0.01-50 mM of NaCl in the solvent.

15. The piezoelectric material of claim 14, comprising 3 mM of NaCl, or 0.0175 wt. % in the solvent.

16. The piezoelectric material of claim 12, wherein the polymer is a polyethylene oxide, polyethylene glycol, polyacrylamide, polyvinyl alcohol, polyamines, polyethyleneimines, quaternary ammonium polymers, carboxymethylated polymers, polyvinylpyrrolidone and copolymers, polyacrylic acid or copolymers.

17. The piezoelectric material of claim 16, comprising 10-90 wt. %. of polymer.

18. The piezoelectric material of any one of claims 1-17, comprising a ratio of polymer to CNCs of 1:1 by weight and a concentration of NaCl of 3 mM in the solvent.

19. The piezoelectric material of any one of claims 1-18, wherein the piezoelectric material is a film, powder or foam.

20. A method of preparing a piezoelectric material comprising the steps of:
dispersing cellulose nanocrystals (CNCs) in a solvent; and
removing of the solvent to produce the piezoelectric material.

21. The method of claim 20, wherein the solvent is removed in the presence of an electric field applied to said CNC dispersed in the solvent.

22. The method of claim 20 or 21, wherein the solvent is removed by evaporation.

23. The method of claim 22, the solvent is removed by evaporation from 0 to 100° C.

24. The method of claim 20 or 21, wherein the solvent is removed by freeze drying or spray drying.

25. The method of any one of claims 20-24, wherein the cellulose nanocrystals are from bleached wood pulp, cotton, grass, wheat straw, bacteria cellulose, or tunicate.

26. The method of any one of claims 20-25, wherein the cellulose nanocrystals are prepared from bleached wood pulp by sulfuric acid hydrolysis.

27. The method of any one of claims 20-26, wherein the cellulose nanocrystals are further modified by ion-exchange, covalently grafting polymers or small molecules, or adsorption of small and controlled amounts of polymers or small molecules.

28. The method of any one of claims 20-27, wherein the solvent is water.

29. The method of any one of claims 16-28, wherein the solvent is dimethyl sulfoxide (DMSO), N-methylpyrrolidone (NMP), dimethyl acetamide (DMA), N,N-dimethylformamide (DMF), pyridine, tetrahydrofuran (THF), or a combination thereof.

30. The method of any one of claims 20-29, comprising 0.01-10 wt. % of CNCs in the solvent.

31. The method of any one of claims 20-30, further comprising an additive in addition to the solvent.

32. The method of claim 31, wherein the additive is a polymer, a salt, or a combination hereof.

33. The method of claim 32, wherein the additive is sodium chloride.

34. The method of claim 33, comprising 0.01-50 mM of NaCl in the solvent.

35. The method of claim 32, wherein the polymer is a polyethylene oxide, polyethylene glycol, polyacrylamide, polyvinyl alcohol, polyamines, polyethyleneimines, quaternary ammonium polymers, carboxymethylated polymers, polyvinylpyrrolidone and copolymers, polyacrylic acid or copolymers.

36. The method of claim 35, comprising 10-90 wt. %. of polymer.

37. The method of claim 35, comprising 0.01-50 mM of NaCl in the solvent.

38. The method of any one of claims 20-37, comprising a ratio of polymer to CNCs of 1:1 by weight and a concentration of NaCl of 3 mM in the solvent.

39. The method of claim 21, wherein the electric field is a direct current or an alternating current source.

40. The method of claim 21, wherein the electric field is from 1 to 1,000 V/m.

41. A method of preparing piezoelectric actuators or transducers comprising the steps of:
sandwiching a CNC-based piezoelectric material between two electrodes; and
laminating the sandwiched piezoelectric material using polymer films.

42. The method of claim 41, wherein the piezoelectric material is as defined in any one of claims 1-19.

43. The method of claim 41, wherein the electrodes are metal foils, conductive coatings, conductive adhesives, conductive polymers, or sputter coated materials.

44. The method of claim 41, wherein the lamination polymer film is polyester, polyvinyl acetate, polyolefin, polyurethane, polyacrylates, polystyrene, halogenated polymers, polysaccharides, rubbers, or a co-polymer hereof.
